(19) United States
(12) Patent Application Publication
(10) Pub. No.: US 2007/0212813 A1
(43) Pub. Date: Sep. 13, 2007

(54) Perforated embedded plane package and method

(76) Inventors: Owen R. Fay, Gilbert, AZ (US); Lizabeth Ann Keser, Chandler, AZ (US); George R. Leal, Cedar Park, TX (US); Robert J. Wenzel, Austin, TX (US)

Correspondence Address: INGRASSIA FISHER & LORENZ, P.C. (FS), 7150 E. CAMELBACK ROAD, SUITE 325, SCOTTSDALE, AZ, 85251, US

(21) Appl. No.: 11/373,541

(22) Filed: Mar. 10, 2006

(51) Int. Cl. H01L 21/00

(52) U.S. Cl. 438/106

(57) ABSTRACT

Methods and apparatus are provided for an electronic assembly (57, 59, 67), comprising: providing multiple electronic devices (32) with primary faces (33) having electrical contacts (39), opposed rear faces (35) and edges (34) therebetween. The devices are mounted primary faces down on a temporary support (7) in openings (48) in a substantially planar sheet (44) attached to the support (70). A plastic encapsulation (36) is formed in contact with at least the lateral edges (34) of the electronic devices (32) and edges (74) of the openings (48). The plastic encapsulation (36) is at least partially cured and the devices (32), sheet (44) and plastic encapsulation (36) separated from the temporary support (70). The devices (32), sheet (44) and plastic encapsulation (36) are desirably but not essentially mounted on a carrier (46) with the primary faces (33) and electrical contacts (39) exposed. Thin film insulators (37) and conductors (38) can be applied to the primary faces (33) to couple electrical contacts (39) on various devices (32) to each other and to external contacts (41), thereby forming an integrated multi-device electronic assembly (67).

### TECHNICAL FIELD

The present invention generally relates to electronic devices, and more particularly relates to packaging of semiconductor and other types of chip devices with a perforated embedded plane.

### BACKGROUND

Semiconductor and other types of electronic devices are often encapsulated wholly or partly in plastic resin to provide environmental protection and facilitate external connection to the devices. For convenience of explanation and not intended to be limiting, the present invention is described for semiconductor devices, but persons of skill in the art will understand that the present invention applies to any type of electronic device that is substantially in chip form. Accordingly, such other types of devices including the non-limiting examples given below, are intended to be included in the terms “device”, “electronic device”, “semiconductor device” and “integrated circuit” whether singular or plural, and the terms “device”, “die” and “chip” are intended to be substantially equivalent. Non-limiting examples of suitable devices are semiconductor integrated circuits, individual semiconductor devices, piezoelectric devices, magnetostrictive devices, solid state filters, magnetic tunneling structures, integrated passive devices such as capacitors, resistors and inductors, and combinations and arrays of any and all of these types of devices and elements. Further, the present invention does not depend upon the types of die or chips being used nor the materials of which they are constructed provided that such materials withstand the encapsulation process.

In certain types of electronic device packaging where connections to multiple devices included in the package are made after encapsulation, there is a problem referred to as “die-drift” or “die-skew” that occurs during encapsulation. This phenomenon occurs as a consequence of the dimensional changes that occur during curing of the plastic encapsulation. The multiple electronic devices are placed in predetermined relative locations on a support or frame prior to encapsulation and then found to have moved relative to each other after encapsulation so that the connection points or bonding pads on the devices are no longer in the same relative locations. This makes it more difficult to couple the bonding pads together and to external connections to integrate the various devices within the package to form the intended final product. Manufacturing yield and cost are adversely affected by die-skew.

Accordingly, it is desirable to provide packaging for electronic devices that avoids or mitigates the adverse effects of die-skew during encapsulation. It is further desirable that the packaging is suitable for use with arrays containing multiple devices and/or multiple types of devices and especially device arrays, where it is desired that the primary faces of the devices are available for electrical connections thereto in predictable locations after the devices are fixed in the encapsulation. In addition, it is desirable that the methods, materials and structures employed be compatible with present day manufacturing capabilities and materials and not require substantial modifications of manufacturing procedures or substantially increase manufacturing costs. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawing figures, wherein like numerals denote like elements, and

FIGS. 1-3 are simplified schematic cross-sectional views of plastic encapsulation process steps for forming a plastic encapsulation in which multiple electronic devices are intended to have their primary connection faces and bonding pads exposed after encapsulation;

FIG. 4 shows a plan view of a panel of encapsulated electronic devices resulting from the process steps of FIGS. 1-3, showing the exposed bonding pads;

FIG. 5 is a simplified schematic cross-sectional view through the device panel of FIGS. 3-4 after further processing, wherein insulating layer(s) and conductor(s) have been provided on its outer surface, interconnecting bonding pads so as to couple various devices together and/or to external terminals;

FIG. 6 shows a plan view of an array of electronic devices before and after encapsulation of the sort illustrated in FIGS. 1-2, illustrating die-skew;

FIG. 7 shows a plan view analogous to FIG. 4 of an array of electronic devices, arranged according to a first embodiment of the present invention wherein a perforated embedded plane is included in the encapsulation to reduce die-skew;

FIG. 8 is a simplified cross-sectional view through the device array of FIG. 7 showing further details of the perforated embedded plane and die arrangement in an encapsulated multi-device panel according to a further embodiment of the present invention;

FIGS. 9-15 are simplified schematic cross-sectional views analogous to those of FIGS. 1-3 and 5 of electronic device plastic encapsulation with a perforated embedded plane at different stages of manufacture, according to a still further embodiment of the present invention;

FIG. 16 is a plan view of the of an array of electronic devices and perforated embedded plane of FIG. 10, viewed toward their rear faces just prior to encapsulation and showing further details;

FIG. 17 is a simplified schematic cross-section through the array of FIG. 16 just after encapsulation; and

FIG. 18 illustrates a method of plastic encapsulation of electronic devices, incorporating the manufacturing stages of FIGS. 9-17, according to a yet further embodiment of the present invention and showing further details.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

For simplicity and clarity of illustration, the drawing figures illustrate the general manner of construction, and descriptions and details of well-known features and techniques may be omitted to avoid unnecessarily obscuring the invention. Additionally, elements in the drawings figures are not necessarily drawn to scale. For example, the dimensions of some of the elements or regions in some of the figures may be exaggerated relative to other elements or regions of the same or other figures to help improve understanding of embodiments of the invention

The terms “first,” “second,” “third,” “fourth” and the like in the description and the claims, if any, may be used for distinguishing between similar elements and not necessarily for describing a particular sequential or chronological order. It is to be understood that the terms so used are interchangeable under appropriate circumstances such that the embodiments of the invention described herein are, for example, capable of operation or use in sequences other than those illustrated or otherwise described herein. Furthermore, the terms “comprise,” “include,” “have” and any variations thereof, are intended to cover non-exclusive inclusions, such that a process, method, article, or apparatus that comprises a list of elements is not necessarily limited to those elements, but may include other elements not expressly listed or inherent to such process, method, article, or apparatus. The terms “left,” right,” “in,” “out,” “front,” “back,” “up,” “down, “top,” “bottom,” “over,” “under,” “above,” “below” and the like in the description and the claims, if any, are used for describing relative positions and not necessarily for describing permanent positions in space. It is to be understood that the embodiments of the invention described herein may be used, for example, in other orientations than those illustrated or otherwise described herein. The term “coupled,” as used herein, is defined as directly or indirectly connected in an electrical or non-electrical manner. The term “bonding pad” singular or plural is intended to refer to any type of electrical connection place on a device and is not limited merely to those suitable for electrical connection by welding or soldering on a wire or other lead.

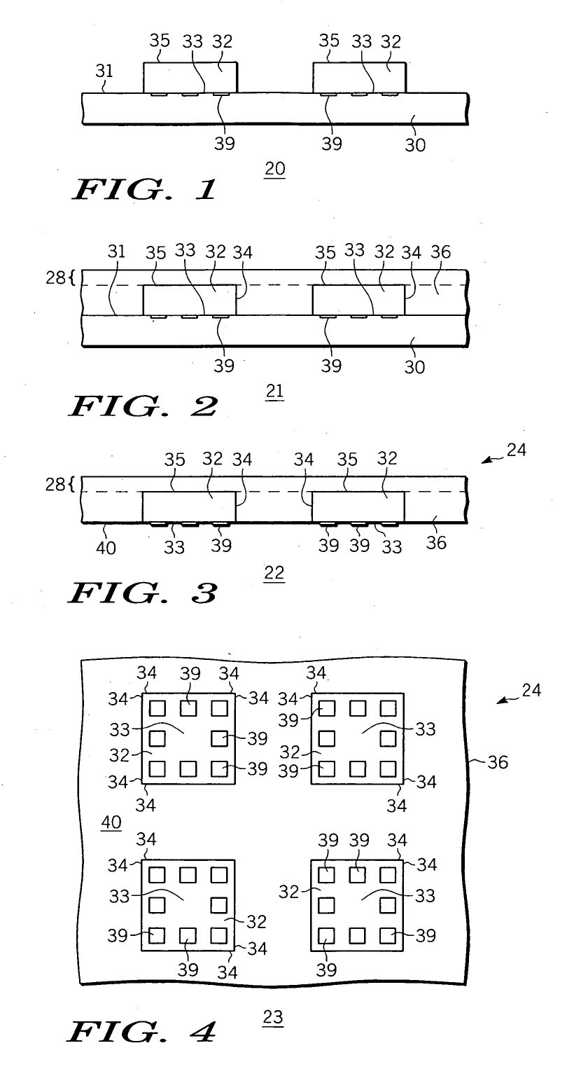

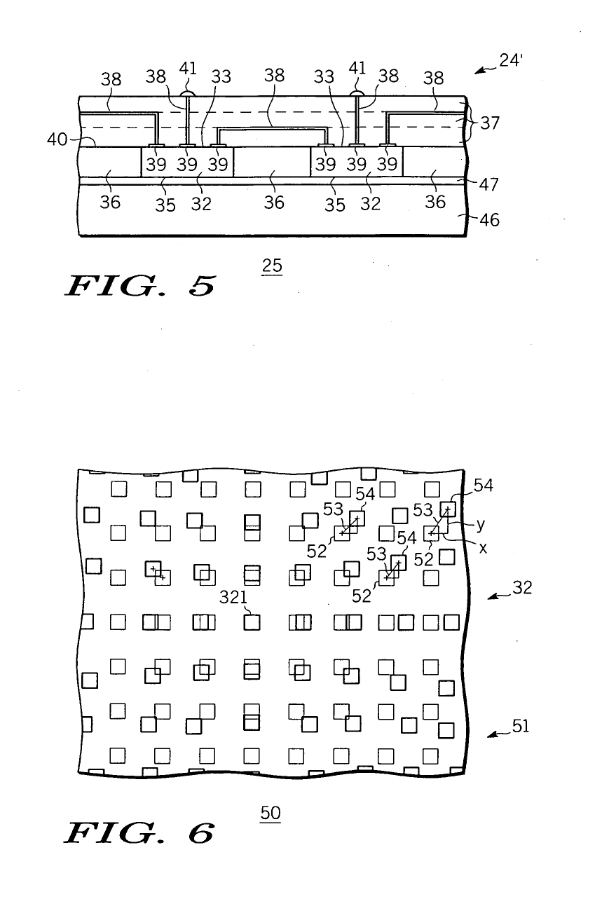

FIGS. 1-6 illustrate the problem of “die-drift” or “die-skew” that occurs with certain types of device packaging. FIGS. 1-3 are simplified schematic cross-sectional views of plastic encapsulation process steps 20, 21, 22 for forming a plastic device package or panel 24 in which multiple electronic devices 32 are encapsulated so as to leave their primary contact faces 33 exposed, FIG. 4 shows plan view 23 of encapsulated device panel 24 resulting from process steps 20, 21, 22, FIG. 5 shows a simplified schematic cross-sectional view similar to that of FIGS. 1-3, but after further processing step 25 wherein various devices making up panel 24 have been interconnected, and FIG. 6 shows plan view 50 of array 51 of electronic devices 32 before and after being packaged as shown in FIGS. 1-4 and illustrating the phenomenon of die-skew during encapsulation.

In step 20 of FIG. 1, temporary substrate 30 is provided having upper surface 31 on which electronic devices 32 are mounted with their primary faces 33 facing toward surface 31 of substrate 30. As used herein the term “primary face” either singular or plural, refers to the face of the electronic device on which is located its principal electrical connections 39, hereafter referred to for convenience and not intended to be limiting, as “bonding pads.” Rear faces 35 of devices 32 remain exposed in step 20. In step 21 of FIG. 2, edges 34 of devices 32 and, optionally rear faces 35 of devices 32, and intervening portions of surface 31 of substrate 30 are covered with resin for plastic encapsulation 36. Primary faces 33 of devices 32 are not covered by encapsulation 36. After encapsulation 36 is cured, then in step 22 of FIG. 3, temporary substrate 30 is removed or separated from encapsulation 36 and devices 32, so that lower surface 40 of encapsulation 36 and primary faces 33 of devices 32 with bonding pads 39 thereon are exposed, thereby providing packaged device panel 24.

FIG. 4 shows plan view 23 looking toward surface 40 of packaged device panel 24 after encapsulation 36 has been provided. For convenience of explanation and not intended to be limiting, packaged device panel 24 in FIG. 4 includes four multi-contact devices 32, but more or fewer devices and different types and shapes of devices may be included in panel 24. Devices 32 are held in plastic encapsulation 36 by edges 34 in one embodiment, and in another embodiment, optionally also by rear faces 35 (see FIGS. 2-3). Devices 32 have electrical connection locations 39 referred to for convenience and inclusively as “bonding pads,” understanding that in various embodiments any type of electrical connection can be made thereto. FIG. 5 illustrates a simplified schematic cross-sectional view through panel 24 resulting from process step 25. In FIG. 5, panel 24′ has been inverted compared to its position in FIG. 4 and panel 24′ has been mounted in this embodiment on support carrier 46 by adhesive layer 47. In processing step 25 according to a further embodiment, insulating layers 37 and conductors 38 have been provided on surfaces 33 and 40 of panel 24 for making electrical connection to bonding pads 39 so as to interconnect various devices 32 and/or couple them to external terminals 41. In this embodiment, portion 28 of encapsulation 36 on rear faces 35 of die 32 has been removed prior to step 25, but this is not essential. Conductors 38 are preferably provided using conventional planar processing technology although in further embodiments other techniques such as screen printing, selective plating or deposition and the like can also be used.

In order to make connections via conductors 38 to bonding pads 39 on panel 24, the relative locations of bonding pads 39 must be known. Accordingly, in manufacturing step 20 of FIG. 1, devices 32 are placed in known locations on temporary support 30. However, during encapsulation step 21 of FIG. 2, devices 32 move to slightly different locations or orientations due to changes that can occur during providing and curing of encapsulation 36. As a consequence, after encapsulation step 21 and temporary support removal step 22, devices 32 are found to be in different locations than where they were originally placed in stage 20. This phenomenon is referred to as “die-drift” or “die-skew” and is illustrated schematically in FIG. 6.

FIG. 6 shows plan view 50 of array 51 of devices 32 before and after encapsulation. The light squares in FIG. 6 identified by reference numbers 52 represent the locations of devices 32 before encapsulation. For convenience of explanation this is shown as a uniformly spaced array of device locations 52. The heavy squares in FIG. 6 identified by reference numbers 54 represent the locations of devices 32 after encapsulation. It will be seen that devices 32 have moved laterally from initial positions 52 by variable amounts of die-skew 53 to subsequent positions 54 as a consequence of applying encapsulation 36 in step 21 of FIG. 2. In the example of FIG. 6, it is assumed that the location of device 321 near the center of array 51 remained substantially unchanged during encapsulation, while devices at increasing distances from device 321 moved by greater and greater amounts of die-skew 53.

In a preferred embodiment, conductors 38 are usually provided for the multiple die in panel 24 at the same time and not individually die-by-die, that is, during common masking and etching steps. Accordingly, it is difficult to take such die-skew into account in preparing the masks needed to carry out interconnection step 25. If die-skew 53 were a perfectly predictable function of the initial positions 52 of die 32 in array 51, then their location after encapsulation might be accurately forecast and taken into account in preparing the various masks for coupling conductors 38 to bonding pads 39 as illustrated in FIG. 5. However, that is not generally the case. Stated another way, the deviation in die-skew can vary significantly with location and from batch to batch and panel to panel. If the deviation in die-skew is substantial, a separate mask set might be needed for each panel. Thus, die-skew can be a significant manufacturing problem. In addition to having devices 32 translate during encapsulation, they may also rotate by varying amounts so that even if the overall device position is little changed or reliably predictable, the location of bonding pads 39 on a particular device may be different than what is anticipated from the movement of the device itself. Thus rotational as well as translational changes can occur as a part of die-skew, making subsequent electrical connection to bonding pads 39 on various devices 32 more difficult and more expensive. This can have adverse affect on manufacturing yield and cost.

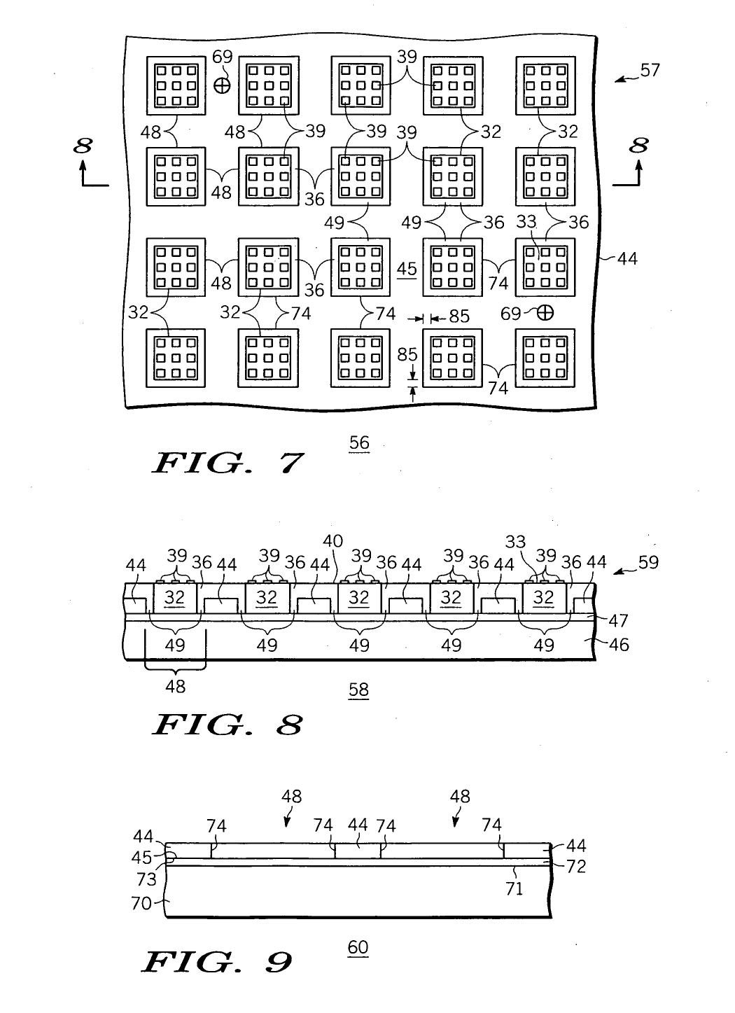

FIG. 7 shows plan view 56 analogous to plan view 23 to FIG. 4, but of array 57 of electronic devices 32, arranged according to a first embodiment of the present invention wherein perforated embedded plane (PEP) 44 laterally surrounds individual devices 32 in the encapsulation to reduce die-skew. FIG. 8 is a simplified cross-sectional view through the device array of FIG. 7 showing further details and with support carrier 46 attached. FIGS. 7-8 show the arrangement of die 32, encapsulation 36 and PEP 44 after encapsulation and attachment of panel 57 to support carrier 46 by adhesive 47, analogous to the arrangement of FIG. 5, but with insulating layers 37 and conductors 38 omitted for clarity. Referring now to FIGS. 7 and 8 together, in a preferred embodiment PEP 44 is preferably a sheet of metal thicker or thinner than devices 32 in which holes or openings 48 have been made by, for example, etching, punching or a combination thereof. Copper is a suitable material for PEP 44, but other well known metal alloys such as for example and not intended to be limiting, Alloy 42 and Alloy 49 can also be used. Alloy 42 and Alloy 49 are well known commercial alloys available in sheet form from many sources, for example, National Electronic Alloys, Inc., of Santa Ana, Calif. However, it is not necessary that PEP 44 be conductive and in further embodiments, other materials such as for example and not intended to be limiting, glass, ceramic, plastic impregnated fiberboard and combinations thereof can also be used. What is important is that PEP 44 be dimensionally stable. It is also desirable that PEP 44 include one or more fiduciary marks 69 adapted to facilitate relative alignment of PEP 44 and devices 32 and/or to align various masks to devices 32 or regions on devices 32 during subsequent processing. As is explained more fully in connection with FIGS. 9-15, devices 32 are placed within openings 48 in PEP 44 and resin encapsulation 36 applied to fill annular spaces or gaps 49 between outer edges 34 of die 32 and inner edges 74 of openings 48 in PEP 44. In a preferred embodiment, after curing of encapsulation 36 composite panel 57 is attached to support carrier 46 by adhesive 47 so that bonding pads 39 on devices 32 are exposed, that is, facing up in FIG, 8, thereby forming composite multi-device panel 59 of FIG. 8.

Comparative die-skew results for the embodiment of the present invention illustrated in FIGS. 7-8 and for the configuration of FIGS. 1-5 are shown in Table I below.

TABLE I
X AND Y DIE-SKEW AND STANDARD DEVIATION (SD)
THEREOF, FOR ARRAYS WITHOUT AND WITH A
PERFORATED EMBEDDED PLANE (PEP)

| | TEST | Relative | Relative | Relative | Relative |
|---|---|---|---|---|---|
| | CONDITIONS | X-Skew_{—} | X-SD_{—} | Y-Skew_{—} | Y-SD |
| (1) | NO PEP | 9.57 | 9.17 | 14.54 | 12.25 |
| (2) | PEP INCLUDED | 0.75 | 0.78 | 1.25 | 1.22 |
| (3) | IMPROVEMENT | 92.2% | 91.5% | 91.4% | 90.0% |

Table I compares the normalized observed X-skew and Y-skew and the normalized observed standard deviation (SD) in the X-skew and the Y-skew for encapsulated device array panels 24, 57 without and with perforated embedded plane (PEP) 44 according to an embodiment of the present invention. The X and Y skew are the distances between the initial and final device positions in the X and Y directions, respectively (see FIG. 6), normalized to the average of the X and Y skew values observed with perforated embedded plane 44 in place. Line (1) of Table I shows the normalized observed data for typical multi-device panel 24 such as that illustrated in FIGS. 1-6 without use of perforated embedded plane (PEP) 44. Line (2) of Table I shows the normalized average of the results from three multi-device panels 57 that included perforated embedded plane (PEP) 44 of FIGS. 7-8. Line (3) of Table I shows the percentage reduction in X and Y skew and the standard deviation (SD) in X and Y skew obtained by incorporating PEP 44 as described above. It is apparent that PEP 44 reduced the amount and the standard deviation of die-skew 53 by over ninety percent. Both factors are important. Reducing the amount of die-skew reduces the amount of compensation that needs to be designed into masks or printing screens used for interconnecting various bonding pads 39, and reducing the standard deviation of die-skew greatly improves the accuracy of the compensation from device to device and can significantly improve the overall manufacturing yield, thereby reducing the cost of multi-device array panels 57, 59.

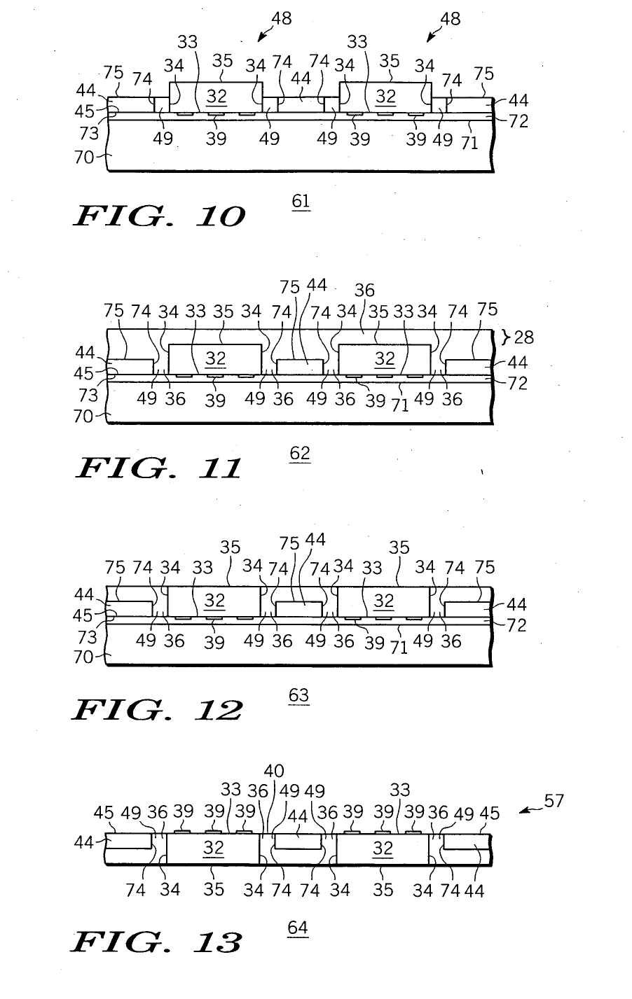

FIGS. 9-15 are simplified schematic cross-sectional views analogous to those of FIGS. 1-3 and 5 of electronic device plastic encapsulation with perforated embedded plane (PEP) 44 at different stages 60 through 66 of manufacture according to further embodiments of the present invention. Like reference numbers are used for like regions. Referring now to manufacturing stage 60 of FIG. 9, temporary substrate 70 having upper surface 71 (analogous to temporary substrate 30 of FIGS. 1-2) is provided. Substrate 70 is conveniently of porous ceramic, for example, alumina of approximately 0.5 micro-meter continuous porosity manufactured by Refractron Technologies of New York, USA, but other comparatively inert materials may also be used. It is preferably porous to assist in later separating it from the encapsulated devices. PEP 44 is mounted on surface 71 of temporary substrate 70 using thin temporary adhesive layer 72 having upper surface 73 in contact with lower surface 45 of PEP 44. In a preferred embodiment, double sided polyimide sticky-tape with silicone adhesive on both sides manufactured by Permacel of New Jersey is used, but in further embodiments other types of non-permanent adhesive materials may also be used. What is important is that adhesive layer 72 withstands the subsequent processing without becoming brittle or permanently fixed in place, since at a later stage of manufacture, PEP 44 with embedded die 32 will be separated from adhesive layer 72. Perforations or openings 48 in PEP 44 have lateral edges 74. PEP 44 is preferably of copper or nickel alloys, such as for example Alloy 42 or 49 but, as noted above, other materials can also be used that are conductive or insulating. In various embodiments, PEP 44 may be thicker or thinner than devices 32. With devices 32 having thicknesses in the range of about 300 to 850 micro-meters, PEP 44 is usefully about 75 to 500 micro-meters thick. Stated another way, PEP 44 is usefully about 25 to 200 percent and more conveniently about 50 to 100 percent and preferably about 60 to 80 percent of the thickness of devices 32. PEP 44 is shown in FIGS. 10-15 as being thinner than die 32, but this is merely to facilitate representation and avoid overlapping or confusing lines in the figures, and is not intended to be limiting.

In stage 61 of FIG. 10, devices 32 are mounted in openings 48 in PEP 44 by placing devices 32 with their primary face 33 on adhesive layer 72, that is, with bonding pads 39 facing adhesive layer 72. Edges 34 of devices 32 face edges 74 of PEP 44 in openings 48, so that there is annular space or gap 49 of mean width 85 surrounding each device 32 separating it from PEP 44 (e.g., see FIG. 7). In various embodiments, width 85 of annular space or gap 49 is usefully in the range of about 25 to 700 micrometers, more preferably about 100 to 500 micrometers and preferably about 200 to 300 micrometers. Stated another way, width 85 of spacer or gap 49 is usefully about 25 to 200 percent of the thickness of PEP 44, more conveniently about 50 to 150 percent of the thickness of PEP 44 and preferably about 75 to 125 percent of the thickness of PEP 44. In stage 62 of FIG. 11, resin encapsulation 36 is applied in at least annular spaces 49 between devices 32 and PEP 44 and, optionally in a further embodiment over rear faces 35 of devices 32 and the rear faces 75 of PEP 44. Type R1007RC-H silica filled epoxy manufactured by the Nagase company of Tokyo, Japan and variations thereof are suitable materials for encapsulation 36, but other encapsulation methods materials well known in the art can also be used,. The structure of FIG. 11 results wherein devices 32 are now held in place relative to PEP 44 by encapsulation 36. Encapsulation 36 is desirably cured using a thermal treatment recommended by the manufacturer for the chosen resin. For the above noted resin, a one or two step cure at temperatures in the range of about 50-170° C. for 30-120 minutes is useful with about 100-150° C. for about 60-90 minutes being preferred.

In a further embodiment in optional manufacturing stage 63 of FIG. 12, portion 28 (see FIG. 11) of encapsulation 36 extending beyond rear faces 35 of devices 32 may be removed (e.g., by grinding or chemical etching or other convenient techniques) to expose rear faces 35 of devices 32. This is referred to conveniently as “backgrind” or “backgrinding” even though in various embodiments other techniques besides grinding may be used to remove portion 28 of encapsulation 36, and such other techniques are intended to be included in the terms “backgrind” and “backgrinding.” Backgrinding facilitates bringing a heat sink in direct contact with rear faces 35 of die 32, but is not essential. After backgrinding stage 63, rear face 75 of PEP 44 may or may not be exposed from encapsulation 36 depending upon the relative thickness of PEP 44 compared to devices 32 and the amount of backgrinding performed.

In manufacturing stage 64 of FIG. 13, temporary support substrate 70 and adhesive layer 72 are removed, thereby exposing primary faces 33 and bonding pads 39 on devices 32, and forming free-standing encapsulated multiple device panel or package 57 wherein devices 32 are held in place at least by their edges 34 embedded in encapsulation 36. Where adhesive 72 is a silicone adhesive, soaking the structure of FIG. 12 in acetone facilitates separation of devices 32, PEP 44, and remaining encapsulation 36 as a unit from temporary support 70, to provide multi-device panel or package 57 of FIG. 13. In FIG. 13, panel 57 has been flipped over compared to its orientation in FIGS. 9-12 so that bonding pads 39 and surfaces 33 now face upward. Bonding pads 39 on various devices 32 and bonding locations on PEP surface 45 are now exposed and available for interconnection in any manner desired by the panel designer or user. In this way, extraordinarily complex functions may be provided by panel 57, since multiple devices 32 of different types, sizes, shapes and functions may be combined and interconnected in a single panel. This is a great convenience where it is desired to use different chips or die made from different materials by different processes to optimize overall performance.

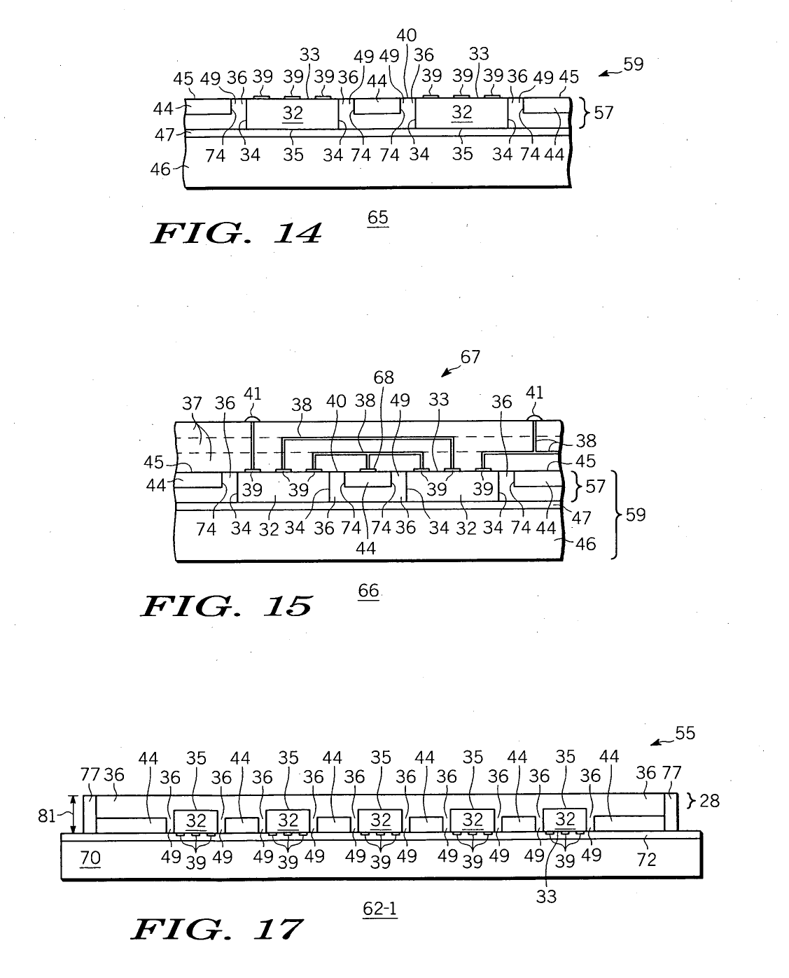

In a further embodiment illustrated by manufacturing stage 65 of FIG. 14, multiple device panel 57 is desirably but not essentially mounted on support carrier 46 by adhesive layer 47 to form composite panel 59 analogous to that of FIG. 8. Adhesive layer 47 is preferably of the same type as adhesive layer 72, but a wide variety of attachment materials may be used in various embodiments. Support carrier 46 may be ceramic, glass, metal, semiconductor, sapphire, fiberglass, various plastics and combinations thereof or other materials well known in the electronic arts. Use of support carrier 46 is convenient for subsequent processing of panel 57 but is not essential. A second cure cycle may be performed if that provided after encapsulation stage 62 has not provided sufficient curing of encapsulation 36. Panels 57, 59 are useful in their present form or, according to other embodiments further processing may be provided to interconnect the various devices in panels 57, 59.

In optional manufacturing stage 66 of FIG. 15 according to further embodiments, one or more insulating layers 37 are provided over surface 33 of devices 32, surface 40 of encapsulation 36 and outer surface 45 of PEP 44. Organic polymers in liquid or dry film form are suitable for insulating layer 37, but in various further embodiments a wide range of other materials well known in the electronic art for interlayer dielectrics may also be used. Layers 37 are patterned and etched to expose bonding pads 39 on devices 32 and, optionally, bonding locations on surface 45 of PEP 44, so that one or more conductors 38 can be applied to interconnect various bonding pads 39 on devices 32 (and optionally, for example, to bonding location(s) 68 on PEP 44) to provide integrated composite multi-device panel 67 comprising whatever circuit or system configuration is desired by the designer of panels 57, 59, 67. Conductors 38 may be metal, metal alloy, doped semiconductor, semi-metals, and/or combinations thereof. Such materials and techniques for applying them are well known in the art. While only three bonding pads are shown on each device in FIG. 15 as being connected and only to an adjacent device and external terminals 41, this is merely for convenience of illustration of the general principal and not intended to be limiting. Persons of skill in the art will understand based on the teachings herein that bonding pads 39 and devices 32 are representative of multiple bonding pads present on multiple devices of the same or different types and the same or different sizes and shapes, and that any number of bonding pads 39 on any of devices 32 may be interconnected in any desired combination to any bonding pads 39 on the same or any other devices 32 or other active or passive device in panels 57, 59 so as to form integrated composite multi-device panel 67 with PEP 44 therein as generally illustrated in FIG. 15. Various fiduciary marks 69 (see FIGS. 7, 16) may be provided on PEP 44 to facilitate placement of devices 32 in openings 48 of PEP 44 and for alignment of various masks or printing layers for forming insulating layers 37, vias needed to expose bonding pads 39, conductors 38 and external connections 41. Because the present invention substantially reduces die-skew, such fiduciary marks are especially useful.

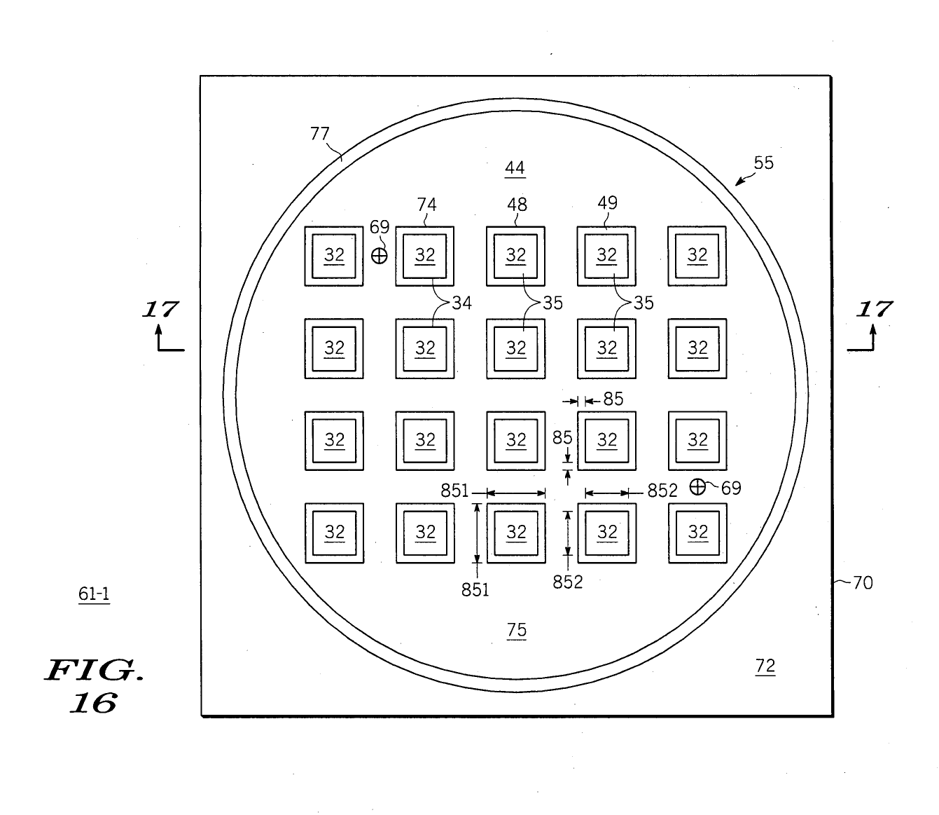

FIG. 16 is a plan view according to a still further embodiment of manufacturing stage 61-1 of array 55 of electronic devices 32 and PEP 44 corresponding to stage 61 of FIG. 10 just prior to encapsulation, viewed toward their rear faces 35, 75 and showing further details. (Just a note here that our panels do not have to be circular in form, they can also be square or rectangular from 100 mm² to 500 mm².) Devices 32 are located in openings 48 in PEP 44, mounted on adhesive layer 72 over temporary substrate 70. Array 55 of devices 32 and PEP 44 are desirably laterally surrounded by mold frame 77, also mounted on adhesive 72. Mold frame 77 is preferably of metal, as for example, and not intended to be limiting, tool steel or stainless steel. While mold frame 77 is shown as being circular in plan view and of substantially rectangular cross-section and array 55 of devices 32 laid out so as to fit within such circular mold frame, this is merely for convenience of explanation and not intended to be limiting. Mold frame 77 may have any convenient plan shape, e.g., circular, elliptical, square, rectangular, and so forth, and any convenient cross-section. Mold frame 77 conveniently serves to limit the lateral extent of encapsulation 36 about to be placed in gaps 49 between edges 34 of die 32 and edges 74 of openings 48 in PEP 44, and persons of skill in the art will understand how to choose a plan shape and cross-section that best suits the particular array of devices that they intend to encapsulate to form a panel according to the teachings herein. FIG. 17 denoted as manufacturing stage 62-1 is a simplified schematic cross-section through array 55 of FIG. 16 along line 17 indicated in FIG. 16 and corresponding to stage 62 of FIG. 11, just after encapsulation 36 has been provided. It will be noted in stage 62-1 of FIG. 17 that mold frame 77 acts as a temporary dam that laterally contains encapsulation 36. In the embodiment of FIG. 17, encapsulation 36 conveniently but not essentially extends over rear faces 35 of devices 32 and rear face 75 of PEP 44. Height 81 of mold frame 77 can be conveniently used to set the thickness of portion 28 of encapsulation 36 over rear faces of devices 32 and PEP 44. While PEP 44 shown as being thinner than devices 32 this is merely for convenience of illustration and not intended to be limiting. PEP 44 may be thicker or thinner than devices 32. Use of mold frame 77 is preferred but not essential.

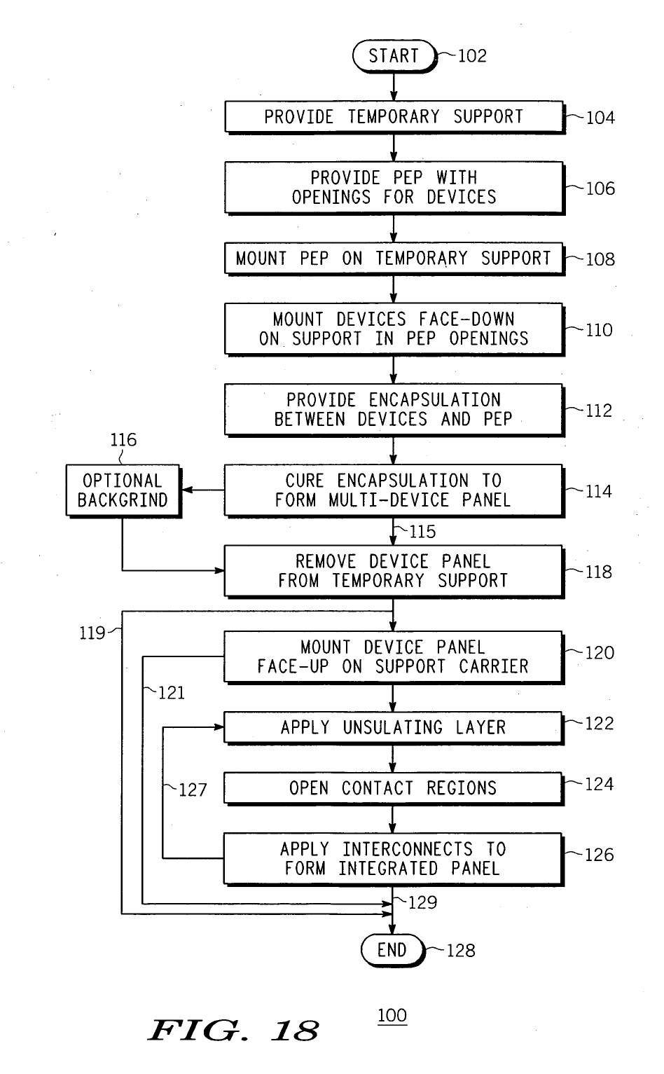

FIG. 18 illustrates method 100 of plastic encapsulation of electronic devices, incorporating the manufacturing stages of FIGS. 9-15, according to still further embodiments of the present invention and showing further details. Method 100 begins at START 102 and initial PROVIDE TEMPORARY SUPPORT step 104 wherein temporary support 70 is provided including adhesive layer 72. In PROVIDE PEP WITH OPENINGS FOR DEVICES step 106, PEP 44 of FIG. 9 is fabricated or obtained as described herein. It is desirable that PEP 44 include one or more fiduciary marks 69 adapted to facilitate relative alignment of PEP 44 and devices 32 or regions on devices 32. Openings 48 in PEP 44 are sized for the die or other chips or devices 32 that are intended to be mounted therein, and where various types of die of different sizes and shapes are to be included in the same panel, different openings may have different sizes and shapes to accommodate die of different sizes and shapes so as to provide frame-shaped gap 49 between edges 34 of die 32 and edges 74 of openings 48 in PEP 44. In FIGS. 7-17 openings 48 and die 32 are assumed to be of uniform size and shape, but this is merely for convenience of explanation and not intended to be limiting. Steps 104 and 106 may be performed in either order. In step 108 corresponding to stage 60 of FIG. 9, PEP 44 is mounted on adhesive layer 72 or otherwise removably attached to temporary support 70. In step 110 corresponding to manufacturing stage 61 of FIG. 10, devices 32 are mounted face-down on adhesive 72 or otherwise removably attached to temporary support 70 in openings 48 of PEP 44. Stage 61-1 of FIG. 16 also shows the results of these two stages. Width 851 (see FIG. 16) of openings 48 in PEP 44 are larger than width 852 of die 32 by twice width 85 of frame-shaped gap 49. Fiduciary marks 69 may be used to accurately position devices 32 in openings 48 so that their location relative to PEP 44 and to each other is well determined. While only two fiduciary marks 69 are shown on PEP 44 in FIGS. 7 and 16, persons of skill in the art will understand that these are merely representative and not intended to be limiting and that any number of fiduciary marks may be provided as a part of PEP 44 adjacent each opening 48 or elsewhere on PEP 44 and on one or both faces 45, 75 of PEP 44, as is desired by the designer. The present invention does not depend upon the exact nature of devices 32 and they can be, for example, integrated circuits, individual devices, filters, magnetostrictive devices, electro-optical devices, electro-acoustic devices, integrated or discrete passive devices such as resistors, capacitors and inductors, or other types of elements and/or combinations thereof, and can be formed of any materials able to withstand the encapsulation process. Non-limiting examples are various organic and inorganic semiconductors, type IV, III-V and II-VI materials, glasses, ceramics, metals, semi-metals, inter-metallics and so forth, according to various embodiments of the present invention. Steps 108 and 110 may be performed in either order but the order shown is preferred.

In subsequent step 112, resin encapsulation 36 is applied to temporary support substrate 70, PEP 44 and devices 32 as described in connection with stage 62 of FIG. 11 and stage 62-1 of FIG. 17, filling at least interstices or gaps 49 between edges 34 of devices 32 and edges 74 of PEP 44. In various embodiments, portion 28 of encapsulation 36 may overly rear faces 35 of devices 32 and rear face 75 of PEP 44 although that is not essential. In step 114 encapsulation 36 is desirably cured as has already been described. It as been found that heating in nitrogen or a substantially inert gas for 30-120 minutes at 50-170° C is useful with 60-90 minutes at about 100-150° C. being preferred. Care should be taken to not render adhesive layer 72 insoluble, thus a two-stage cure may be desirable depending upon the choice of adhesive layer 72. In further embodiments, optional backgrind step 116 may then be performed as has already been described in connection with FIGS. 11-12 wherein portion 28 of encapsulation 36 is removed by grinding, etching, a combination thereof or other convenient means, leaving PEP 44 with interspersed die 32, to form device panel 57. Panel 57 is desirably about 200-1000 micrometers thick with about 550-750 micrometers being preferred, depending upon the thickness of devices 32 and PEP 44. If wet grinding is used during optional backgrind step 116, it is desirable to subject device panel 57 to a brief drying cycle to remove any moisture that may have been absorbed during backgrind. About 10-20 minutes at 80-120° C. is useful with about 15 minutes at about 100° C. being preferred. Alternatively in various embodiments, method 100 may proceed directly from step 114 to step 118 as shown b y path 115, depending upon the needs of the designer of the device array being formed.

In an embodiment including step 118, device panel 57 is separated from temporary support substrate 70 as shown in connection with FIG. 13. Substrate 70 can be released from device panel 57 by soaking the combination of panel 57 and substrate 70 in solvents that soften adhesive layer 72. The choice of solvent will depend on the choice of adhesive layer 72. In a preferred embodiment where adhesive layer 72 comprises double sided polyimide tape with silicone adhesive surfaces, acetone is a suitable solvent. The resulting structure is shown in FIG. 13. Device panel 57 is useful as is and in such embodiment method 100 can, optionally proceed to END 128 as shown by path 119, but in a further embodiment it is preferable to mount device panel 57 on support carrier 46 as indicated in step 120 and shown in FIG. 14. In a preferred embodiment, adhesive 47 is used to mount device panel 57 on support carrier 46, as has already been described in connection with FIG. 14, thereby forming reinforced device panel 59. Reinforced device panel 59 is useful as-is and in such embodiment method 100 can optionally, proceed to END 128 after step 120 as indicated by path 121. However, in a further embodiment it is preferably in order to provide an electrically integrated panel such as is illustrated in FIG. 15, to proceed with subsequent steps 122, 124, 126 wherein some or all of bonding pads 39 on devices 32 are interconnected in the desired manner and coupled to appropriate input-output (I/O) terminals 41 (e.g., see FIG. 15). For embodiments wherein such an integrated panel is desired, then in step 122 insulating layer 37 is applied over faces 33 of devices 32 and surface 45 of PEP 44, and in step 124 vias are opened in insulating layer 37 to the appropriate bonding pads 39, and in step 126 they are electrically coupled by applying conductive interconnects 38. Persons of skill in the art will understand based on the teachings herein, that more than one insulating layer 37, more than one set of vias and more than one conductor layer 38 may be required to achieve the desired interconnections of multiple devices 32 in panel 59. Accordingly, as indicated by path 127 corresponding to such further embodiments, steps 122, 124, 126 may be repeated as often as necessary in order to achieve the desired interconnections within panel 59 and to external terminals 41. When the desired interconnectivity has been achieved, then according to such embodiments, method 100 proceeds to end 128 as shown by path 129 and integrated multi-device panel 67 such as is illustrated in FIG. 15 is obtained.

According to a first exemplary embodiment there is provided a method for forming an electrical assembly, comprising, providing multiple electronic devices with primary faces where electrical contacts are located, opposed rear faces, and edges extending between the primary and rear faces, providing a perforated sheet having multiple openings therein sized to accept the multiple electronic devices and one or more fiduciary marks for alignment, providing a temporary support adapted to receive the multiple electronic devices and the perforated sheet on a principal surface thereof, then in either order, placing the conductive sheet and the multiple electronic devices on the principal surface of the temporary substrate, with the multiple electronic devices in the openings in the perforated sheet so that gaps are located between the edges of the electronic devices and edges of the openings in the perforated sheet, and wherein the primary faces of the electronic devices are oriented toward the principal surface of the temporary support, providing plastic encapsulation at least in the gaps, separating the devices, the conductive sheet and the plastic encapsulation in the gaps from the temporary support, thereby providing a panel containing the multiple electronic devices and the perforated sheet joined by the plastic encapsulation, and attaching the panel containing the multiple electronic devices and the perforated sheet joined by the plastic encapsulation to a support carrier. According to a further exemplary embodiment, the step of providing a temporary support comprises, providing a temporary support having an adhesive layer on the principal surface. According to a still further exemplary embodiment, the placing steps comprise in either order, attaching the perforated sheet and the multiple electronic devices to the temporary support by placing them in contact with the adhesive layer. According to a yet further exemplary embodiment, the adhesive layer comprises a double-sided sticky-tape. According to a yet still further exemplary embodiment, the perforated sheet is a copper or a nickel alloy. According to a still yet further embodiment, the step of providing plastic encapsulation at least in the gaps, comprises, forcing the plastic encapsulation into the gaps and then curing the plastic encapsulation in the gaps. According to another exemplary embodiment, the step of providing plastic encapsulation at least in the gaps comprises, providing the plastic encapsulation in the gaps and over rear faces of the multiple electronic devices and the perforated sheet. According to a yet another exemplary embodiment, the method further comprises prior to the separating step, backgrinding the plastic encapsulation to expose the rear faces of the multiple electronic devices. According to a still another exemplary embodiment, the gaps have a width in the range of 25 to 200 percent of the thickness of the perforated sheet. According to a still yet another exemplary embodiment, the method further comprises after the attaching step, interconnecting electrical contacts on some of the multiple electronic devices.

According to a second exemplary embodiment, there is provided a method for forming a panel of multiple electronic devices, comprising, providing multiple electronic devices with first faces having bonding pads thereon, opposed rear faces, and edges extending between the first faces and rear faces, providing a temporary support having a principal face, providing a conductive plane having a first thickness and having openings therein adapted to receive the multiple electronic devices, mounting the conductive plane and the multiple electronic devices on the temporary support with the multiple electronic devices located in the openings in the conductive plane with their bonding pads oriented toward the principal face, and wherein a gap separates the edges of each of the multiple electronic devices from each opening in the conductive plane and the gap has a width in the range of 25 to 200 percent of the thickness of the conductive plane, providing plastic encapsulation at least between edges of the multiple electronic devices and the openings in the conductive plane on the temporary support, curing the plastic encapsulation at least sufficiently to substantially fix the multiple electronic devices and the conductive plane in the encapsulation, thereby forming a panel of multiple electronic devices on the temporary support, separating the panel from the temporary support so that the bonding pads are exposed, and interconnecting some of the bonding pads on the panel. According to a still further exemplary embodiment the method further comprises after the separating step and before the interconnecting step mounting the panel on a carrier with the rear faces of the multiple electronic devices facing the carrier and the bonding pads exposed. According to a yet further exemplary embodiment, the interconnecting step comprises, applying one or more insulating layers over the multiple electronic devices, opening vias to at least some of the bonding pads, and providing conductive interconnects extending through some of the vias in the one or more insulating layers to electrically couple some of the bonding pads to each other or to external connections to the panel. According to a still yet further exemplary embodiment, the conductive plane comprises one or more fiduciary marks adapted for use in alignment. According to a yet still further exemplary embodiment, the openings in the conductive plane exceed lateral dimensions of one or more of the multiple electronic devices by an amount in the range of 50 to 1400 micrometers. According to another exemplary embodiment, the step of providing plastic encapsulation comprises, laterally surrounding the conductive plane with a mold frame coupled to the temporary support and adapted to constrain lateral spread of the plastic encapsulation.

According to a third exemplary embodiment, there is provided an integrated electronic assembly, comprising, multiple electronic devices having front faces with bonding pads thereon, opposed rear faces and edges extending therebetween, a substantially planar sheet having openings therein in which the multiple electronic devices are located, plastic encapsulation in the openings in the substantially planar sheet coupling the edges of the electronic devices to the substantially planar sheet, a support carrier coupled to the rear faces of the multiple electronic devices, and interconnections extending between some of the multiple electronic devices over portions of the substantially planar sheet between the openings thereby coupling some of the bonding pads together to form the integrated electronic assembly on the support carrier. According to a still further exemplary embodiment, the rear faces of the multiple electronic devices are free of the plastic encapsulation. According to a yet further exemplary embodiment, the plastic encapsulation further extends over rear faces of the multiple electronic devices and the substantially planar sheet. According to a still yet further exemplary embodiment, the substantially planar sheet comprises one or more fiduciary marks.

While at least one exemplary embodiment has been presented in the foregoing detailed description, it should be appreciated that a vast number of variations exist. For example, and not intended to be limiting, die 32 and PEP 44 may be of any type and technology and not limited merely to the examples given. Similarly, while various preferred materials and packaging methods for the die panel are described herein, persons of skill in the art will understand that a large number of alternatives exist according to different embodiments of the present invention, for example and not intended to be limiting, for various support substrates and carriers and PEPs and adhesives and other layers used herein, and such are intended to be included in the scope of the claims that follow. Further, the exemplary implementations and embodiments presented herein yield die panels in various stages of completion that are useful in intermediate as well as finished form and such are intended to be included within the scope of the claims that follow.

It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A method for forming an electrical assembly, comprising:
providing multiple electronic devices with primary faces where electrical contacts are located, opposed rear faces, and edges extending between the primary and rear faces;
providing a perforated sheet having multiple openings therein sized to accept the multiple electronic devices and one or more fiduciary marks for alignment;
providing a temporary support adapted to receive the multiple electronic devices and the perforated sheet on a principal surface thereof;
then in either order, placing the conductive sheet and the multiple electronic devices on the principal surface of the temporary substrate, with the multiple electronic devices in the openings in the perforated sheet so that gaps are located between the edges of the electronic devices and edges of the openings in the perforated sheet, and wherein the primary faces of the electronic devices are oriented toward the principal surface of the temporary support;
providing plastic encapsulation at least in the gaps;
separating the devices, the conductive sheet and the plastic encapsulation in the gaps from the temporary support, thereby providing a panel containing the multiple electronic devices and the perforated sheet joined by the plastic encapsulation; and
attaching the panel containing the multiple electronic devices and the perforated sheet joined by the plastic encapsulation to a support carrier.

2. The method of claim 1, wherein the step of providing a temporary support comprises, providing a temporary support having an adhesive layer on the principal surface.

3. The method of claim 2, wherein the placing steps comprise in either order, attaching the perforated sheet and the multiple electronic devices to the temporary support by placing them in contact with the adhesive layer.

4. The method of claim 3, wherein the adhesive layer comprises a double-sided sticky-tape.

5. The method of claim 1, wherein the perforated sheet is a copper or a nickel alloy.

6. The method of claim 1, wherein the step of providing plastic encapsulation at least in the gaps, comprises, forcing the plastic encapsulation into the gaps and then curing the plastic encapsulation in the gaps.

7. The method of claim 1, wherein the step of providing plastic encapsulation at least in the gaps, comprises, providing the plastic encapsulation in the gaps and over rear faces of the multiple electronic devices and the perforated sheet.

8. The method of claim 7, further comprising prior to the separating step, backgrinding the plastic encapsulation to expose the rear faces of the multiple electronic devices.

9. The method of claim 1, wherein the gaps have a width in the range of 25 to 200 percent of the thickness of the perforated sheet.

10. The method of claim 1, further comprising after the attaching step, interconnecting electrical contacts on some of the multiple electronic devices.

11. A method for forming a panel of multiple electronic devices, comprising:
providing multiple electronic devices with first faces having bonding pads thereon, opposed rear faces, and edges extending between the first faces and rear faces;
providing a temporary support having a principal face;
providing a conductive plane having a first thickness and having openings therein adapted to receive the multiple electronic devices;
mounting the conductive plane and the multiple electronic devices on the temporary support with the multiple electronic devices located in the openings in the conductive plane with their bonding pads oriented toward the principal face, and wherein a gap separates the edges of each of the multiple electronic devices from each opening in the conductive plane and the gap has a width in the range of 25 to 200 percent of the thickness of the conductive plane;
providing plastic encapsulation at least between edges of the multiple electronic devices and the openings in the conductive plane on the temporary support;
curing the plastic encapsulation at least sufficiently to substantially fix the multiple electronic devices and the conductive plane in the encapsulation, thereby forming a panel of multiple electronic devices on the temporary support;
separating the panel from the temporary support so that the bonding pads are exposed; and
interconnecting some of the bonding pads on the panel.

12. The method of claim 11, further comprising after the separating step and before the interconnecting step mounting the panel on a carrier with the rear faces of the multiple electronic devices facing the carrier and the bonding pads exposed.

13. The method of claim 12, wherein the interconnecting step comprises:
applying one or more insulating layers over the multiple electronic devices;
opening vias to at least some of the bonding pads; and
providing conductive interconnects extending through some of the vias in the one or more insulating layers to electrically couple some of the bonding pads to each other or to external connections to the panel.

14. The method of claim 11, wherein the conductive plane comprises one or more fiduciary marks adapted for use in alignment.

15. The method of claim 11, wherein the openings in the conductive plane exceed lateral dimensions of one or more of the multiple electronic devices by an amount in the range of 50 to 1400 micrometers.

16. The method of claim 11, wherein the step of providing plastic encapsulation comprises, laterally surrounding the conductive plane with a mold frame coupled to the temporary support and adapted to constrain lateral spread of the plastic encapsulation.

17. An integrated electronic assembly, comprising:
multiple electronic devices having front faces with bonding pads thereon, opposed rear faces and edges extending therebetween;
a substantially planar sheet having openings therein in which the multiple electronic devices are located;
plastic encapsulation in the openings in the substantially planar sheet coupling the edges of the electronic devices to the substantially planar sheet;
a support carrier coupled to the rear faces of the multiple electronic devices; and
interconnections extending between some of the multiple electronic devices over portions of the substantially planar sheet between the openings thereby coupling some of the bonding pads together to form the integrated electronic assembly on the support carrier.

18. The assembly of claim 17, wherein the rear faces of the multiple electronic devices are free of the plastic encapsulation.

19. The assembly of claim 17, wherein the plastic encapsulation further extends over rear faces of the multiple electronic devices and the substantially planar sheet.

20. The assembly of claim 17, wherein the substantially planar sheet comprises one or more fiduciary marks.
